(19) United States
(12) Patent Application Publication
(10) Pub. No.: US 2011/0097551 A1
(43) Pub. Date: Apr. 28, 2011

(54) COATING AND A METHOD FOR PRODUCING A COATING

(76) Inventors: Kaj Pischow, Mikkeli (FI); Martin Andritschky, Braga (PT)

(21) Appl. No.: 12/934,143

(22) PCT Filed: Mar. 27, 2009
(86) PCT No.: PCT/FI2009/050233

§ 371 Date: Dec. 9, 2010

(30) Foreign Application Priority Data
Mar. 28, 2008 (FI) 20080248

(51) Int. Cl. B32B 3/30; C23C 16/505; C23C 16/04; C23C 16/511

(52) U.S. Cl. 428/172; 427/569; 427/255.28; 427/575

(57) ABSTRACT

What is described here is a method of producing a patterned coating by PECVD without additional production steps. The proposed method produces a moth-eye like macrostructure on a surface by direct deposition. Additionally, the macrostructure may be modulated by a microstructure with a surface texture in the subwavelength range. As a result, protective, antireflective coating comprising a carrier layer consisting of an optically transparent material, which, at least on one surface side, presents antireflective properties with respect the optical wavelengths of the radiation incident on the surface can be produced, as well as surface structures which are the basis for superhydrophobic surface properties.

### BACKGROUND OF THE INVENTION

1. Field of the Invention

The present invention is related generally to surface protection coatings. More specifically, the present invention is related to plastic and metal components that are associated with a protective or hydrophobic coating.

2. Background Technology

Surface protective coatings on plastic or metal substrates produced by PECVD (Plasma Enhanced Chemical Vapor Deposition) have a wide potential application due to their hardness, abrasion resistance, adherence, attractive colour and other properties. Transparent surface protective coatings on transparent or metallic substrates produced by PECVD are prone to the appearance of so-called Newton rings or refraction fringes due to interference effects in in-door lighting conditions (One decorative effect is the iridescent visual effect created by multireflections). These interference effects inhibit the usage of the coating in a decorative function. The proposed surface patterning of the protective coating suppress the interference effects at the first surface, suppress the Newton rings and fringes and increase the optical transmittance of the coating. The application of these protective coatings abranges transparent plastic windows for handheld devices, all painting applications where the part is protected by a transparent top coat, all decorative and functional metal parts in devices where the abrasion resistance of the metal is not sufficient for the envisaged application, vacuum metallized plastic parts which need a topcoat for the protection of the metallic layer.

It is a well known technique to impart antireflective properties to an object, such as a sheet glass, by introducing microscopic corrugations to the surface of the object [see for instance: “Artificial Media Optical Properties-Subwavelength Scale”, Lalanne and Hutley, published in the Encyclopedia of Optical Engineering, 2003]. We refer to such low reflectance surfaces as microstructured antireflective textures (MARTs). The microcorrugations of a MART typically are on a length scale sufficiently small usually in the sub-wavelength regime—to prevent diffusive scattering of light commonly exhibited by a “matte” or “non-glare” finish. That is, a MART truly reduces the hemispherical reflectance from a surface rather than merely scattering or diffusing the reflected wavefront. In this regime, the interaction of light with a microstructured surface is usually described using an “effective medium theory”, under which the optical properties of the microtextured surface are taken to be a spatial average of the material properties in the region [Raguin and Morris, “Antireflection Structured Surfaces for the Infrared Spectral Region”, Applied Optics Vol. 32 No. 7, 1993]. The hemispherical reflectance of light from glass back into air can be less than 0.5% for a properly designed MART. Such a small hemispherical reflectance is impossible if the surface corrugations are much larger than the wavelength of incident light. For visible light, the length scale of MART corrugations is typically around one-half micron.

Perhaps the best known MART is the so-called “moth-eye” surface which possesses optical properties that may be more effective than commercially available thin-film coatings. Thin-film antireflective coatings usually consist of one or more layers of materials optically dissimilar from the substrate, and are sputtered or evaporated onto the substrate in precisely controlled thicknesses. Moth-eye surfaces are comprised of a regular array of microscopic protuberances, and are presently available from a small number of manufacturers worldwide (for example Autotype International Limited, in Oxon, England). Other examples of MARTs are the “SWS surface” [Philippe Lalanne, “Design, fabrication, and characterization of subwavelength periodic structures for semiconductor antireflection coating in the visible domain” pp. 300-309, in SPIE Proceedings Vol. 2776, (1996)], and the “MARAG” surface [Niggemann et al, “Periodic microstructures for large area applications generated by holography” pp 108, Proceedings of the SPIE vol. 4438 (2001)].

Surface protective coatings, transparent or opaque, on transparent or metallic substrates produced by PECVD can be used to increase the hydrophobicity of the surface. The hydrophobicity of the surface depends on the chemical composition of the top layer and on the topography of the surface. The surface pattern created by the proposed deposition technology is capable to increase the water contact angle from between 95° . . . 105° to more than 150° which is a significant increase in hydrophobicity.

### SUMMARY OF THE INVENTION

The formation of a thin film on a substrate by chemical reaction of gases is a commonly used industrial process. Such a deposition process is referred to as chemical vapor deposition or “CVD.” Conventional thermal CVD processes supply reactive gases to the substrate surface where heat-induced chemical reactions take place to produce a desired film. Plasma enhanced CVD techniques, on the other hand, promote excitation and/or dissociation of the reactant gases by the application of radio frequency (RF) or microwave energy. The high reactivity of the released species reduces the energy required for a chemical reaction to take place, and thus lowers the required temperature for such PECVD processes. PECVD allows the deposition of hard protective coatings on plastic and metallic substrates. The proposed process influences the gas flow onto the substrate during the end of the deposition of the hard layer with an aim to form a patterned surface. The patterned layer may have a so-called moth-eye effect, suppressing such multiple optical reflections. Another embodiment of the proposed process is a surface pattern which enhances the hydrophobicity of a surface to a contact angle with water greater than 150°.

These and other features of embodiments of the present invention will become more fully apparent from the following description and appended claims, or may be learned by the practice of the invention as set forth hereinafter.

According to an exemplary aspect of the invention, there is provided a deposition process or method for depositing a patterned coating, the method comprising: depositing a patterned coating directly onto a curved or planar substrate through a patterning device by plasma enhanced chemical vapor deposition.

In an embodiment, the patterned coating comprises or consists of a plurality of protrusions. In an embodiment, the diameter of the protrusions is between 1 to 100 μm, the height of the protrusions between 0.01 to 0.5 μm and the spacing between the protrusions 10 to 500 μm. A small resolution patterning can thereby be obtained. The patterned coating may be uniform.

In an embodiment there is provided a method of producing a patterned coating by PECVD without additional production steps. An embodiment excels itself by the provision that the proposed method produces a moth-eye like macrostructure on a surface by direct deposition. Additionally, the macrostructure may be modulated by a microstructure with a surface texture in the subwavelength range. As a result, protective, antireflective coating comprising a carrier layer consisting of an optically transparent material, which, at least on one surface side, presents antireflective properties with respect the optical wavelengths of the radiation incident on the surface can be produced, as well as surface structures which are the basis for superhydrophobic surface properties.

### BRIEF DESCRIPTION OF THE DRAWINGS

To further clarify the above and other advantages and features of the present invention and its embodiments, a more particular description of the invention will be rendered by reference to specific embodiments thereof that are illustrated in the appended drawings. It is to be appreciated that these drawings depict only typical embodiments of the invention and are therefore not to be considered limiting of its scope. The invention will be described and explained with additional specificity and detail through the use of the accompanying drawings in which:

FIG. 1a and FIG. 1b represent a schematic depiction of typical production set-ups according to embodiments of the invention;

FIG. 2 shows a schematic depiction of a patterned coating;

FIG. 3a is a schematic depiction of an optical structure according to an embodiment of the present invention and FIG. 3b shows the optical reflection pattern of the depicted structure.

FIG. 4a is a schematic depiction of a structure according to another embodiment of the present invention, and FIG. 4b shows the optical reflection pattern of the depicted structure.

### DETAILED DESCRIPTION OF THE INVENTION

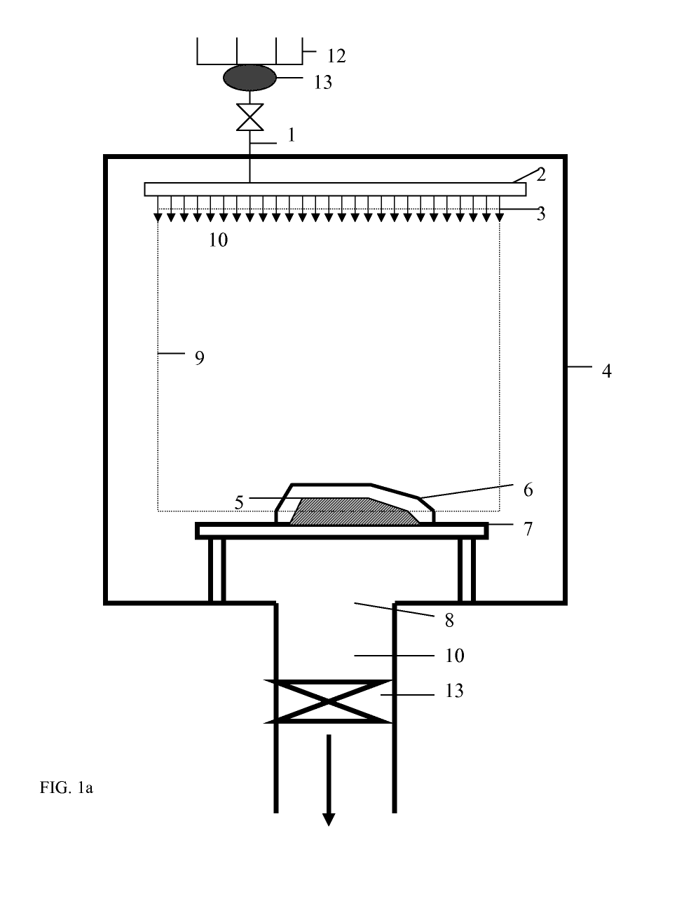

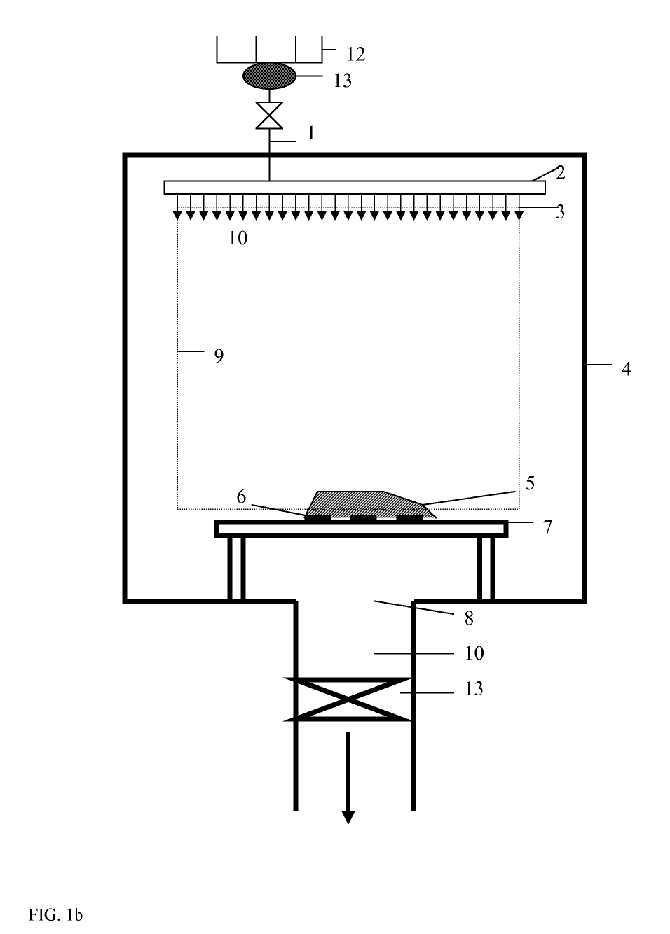

One suitable PECVD (Plasma Enhanced Chemical Vapor Deposition) apparatus in which the method of the present invention can be carried out is shown in FIGS. 1a and 1b, which is a vertical, cross-sectional view of a PECVD system 4, having a vacuum or processing chamber.

PECVD system 4 contains a gas distribution manifold faceplate 2 for dispersing process gases 3 to a substrate 5 that rests on a pedestal 7, centered within the process chamber.

Deposition and carrier gases are introduced into chamber 4 through perforated holes of a conventional flat, circular gas distribution 2. More specifically, deposition process gases flow into the chamber from the inlet manifold 1 through a conventional perforated blocker and then through holes in gas distribution faceplate 2.

Before reaching the manifold 1, deposition and carrier gases are input from gas sources 12 through gas supply lines into a mixing system 13 where they are combined and then sent to manifold 1. Generally, the supply line for each process gas includes (i) several safety shut-off valves (not shown) that can be used to automatically or manually shut-off the flow of process gas into the chamber, and (ii) mass flow controllers (also not shown) that measure the flow of gas through the supply line. When toxic gases are used in the process, the several safety shut-off valves are positioned on each gas supply line in conventional configurations.

The deposition process performed in PECVD system 4 can be either a remote plasma-enhanced process or a cathodic plasma-enhanced process. In a remote plasma-enhanced process, an RF power supply applies electrical power between the insulated gas distribution faceplate 2 and an auxiliar additional electrode or the chamber wall. The pedestal 7 is electrically connected to the chamber wall. In a cathodic plasma-enhanced process, an RF power supply applies electrical power between the insulated pedestal 7 and an auxiliar additional electrode or the chamber wall. The gas distribution face plate is than electrically connected to the chamber wall. In both cases the RF power excites the process gas mixture to form plasma within the cylindrical region 9 between the faceplate 2 and the pedestal 7. (This region will be referred to herein as the “reaction region”). Constituents of the plasma react to deposit a desired film on the surface of the substrate supported on pedestal 7. RF power supply typically supplies power at a high RF frequency (RF) of 13.56 MHz or higher.

The substrates 5 are located on the pedestal 7, whereby flat substrates can be located directly onto the pedestal, a curved substrate is located on a holding device with one surface with the same curvature as the substrate in contact with the substrate and with a flat surface in contact with the pedestal 7.

In one preferred configuration depicted in FIG. 1a, a mesh or a perforated plate 6 is located between substrates and the reaction region (This mesh or perforated plate will be referred herein as “patterning device”). The patterning device 6 is connected to the pedestal 7. The distance between patterning device 6 and substrate surface can vary between 0.1 and 15 mm depending on the hole size and hole distance. In some embodiments, the patterning device 6 is less than 2 mm thick. The patterning device 6 may be made out of metal foil, textile web, glass, ceramics or plastic material.

In an alternative configuration depicted in FIG. 1b, the substrate 5 is located directly on top of the patterning device 6. The patterning device 6 is connected to the pedestal 7. In some embodiments, the patterning device 6 is be made out of electrical conductive foil or wires.

The remainder of the gas mixture, that is not deposited in a layer, including reaction byproducts, is evacuated from the chamber by a vacuum pump (not shown). Specifically, the gases are exhausted through an annular orifice 8 through a downward-extending gas passage 10, past a vacuum shut-off valve 13, and into the exhaust outlet (not shown) that connects to the external vacuum pump (not shown) through a foreline (also not shown).

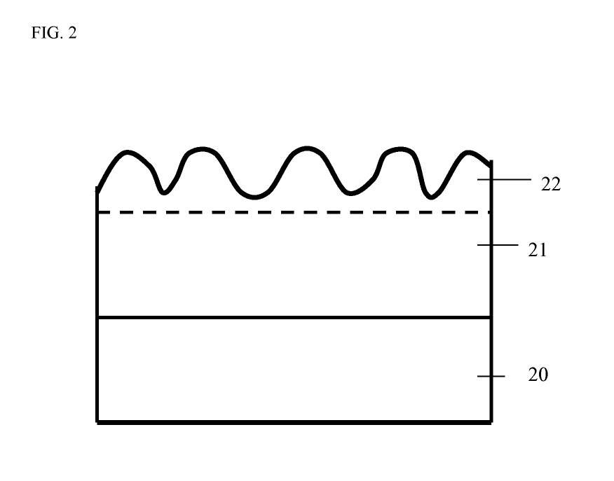

FIG. 2 depicts a typical structure on a transparent or opaque substrate 20, which includes a hard protective light transmissive layer 21 having a macrostructured surface relief pattern 22 the outer surface thereof.

Suitable materials for the substrate are almost all plastics used for injection molding including plastic materials such as polyvinyl chloride, polycarbonate, PC-ABS polyacrylate and PET, metals like stainless steel and other steel alloys, aluminium and magnesium alloy.

The substrates may be pre-coated by different technologies, e.g., plastic substrates could be painted with a base coat to smoothen the surface and could be metallized with a metallic layer a thickness of 10 to 100 nm in a vacuum or electro-chemical process. This metal layer could consist in consisting in aluminium, indium, chromium, silicon, iron, nickel, tin or alloys of these materials.

Typical precursors and the resulting coating composition abrange transparent coatings type SiOₓ based on pre-cursers like TMOS, HMDSO, HMDS, OCMTS etc, TiOₓ based on pre-cursers like TiCl₄, Titanium tetraisopropoxide, (TiO)₂ (tertiarybutyl-acetoacetate)₂, TiO[CH₃COCH_C(O—)CH₃]₂ and alloys of TiOₓ and SiOₓ and others. Argon, helium and oxygen may be used as carrier gases and to enhance the plasma formed in region 9. Deposition conditions for the PECVD deposition process are well known by those skilled in the art. Layer 21 and 22 can be made based on the same or different precursors at similar deposition conditions.

During a typical production run, the PECVD reactor would be set (1) to deposit the hardcoating 21 as described above with the desired thickness without the use of the patterning device. In a subsequent step (2), the patterned layer 22 is applied in the same or similar reactor but by positioning the patterning device above or below the substrate into the reaction zone. If desired, a micropattern can be superimposed (3) on the macropattern obtained in (2) by repeating the patterning from step (2) but with a different patterning structure (hole size, hole form and hole distance) in the patterning device.

### Embodiment 1

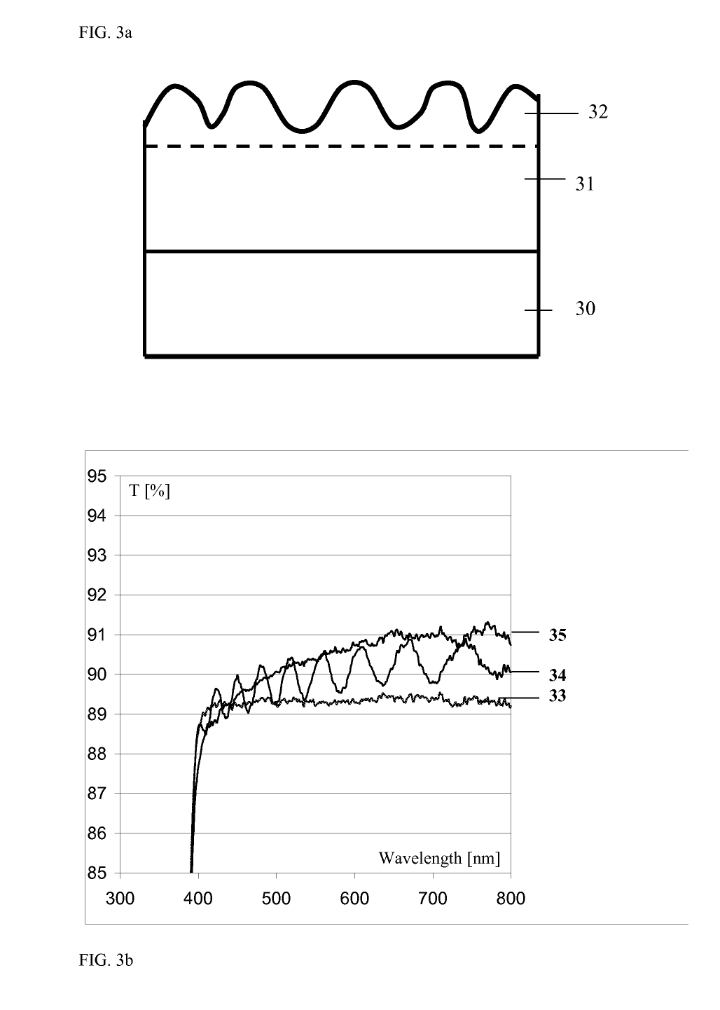

In one preferred embodiment, the substrate consists out of a flat or curved transparent plastic material like PMMA 30. HMDS is used as precursor, Oxygen and Helium as carrier gases. Firstly a thick layer 2 . . . 10 μm of SiOₓ 31 is applied, while removing the patterning device. Secondly, an about 1 . . . 2 μm thick SiOx layer 32 is applied with the patterning device, as depicted in FIG. 3a. The patterning device consists out of a 0.2 mm thick metal foil with a regular pattern of holes with a diameter of 0.15 mm, spaced about 0.3 mm. FIG. 3b depicts the optical transmittance pattern of the PMMA substrate 33, with hard protective layer but without the patterned layer 34 and with hard protective layer and with the patterned layer 35 described in step 2. The suppression of the interference effect, its associated fringes and reduction of reflections are apparent.

### Embodiment 2

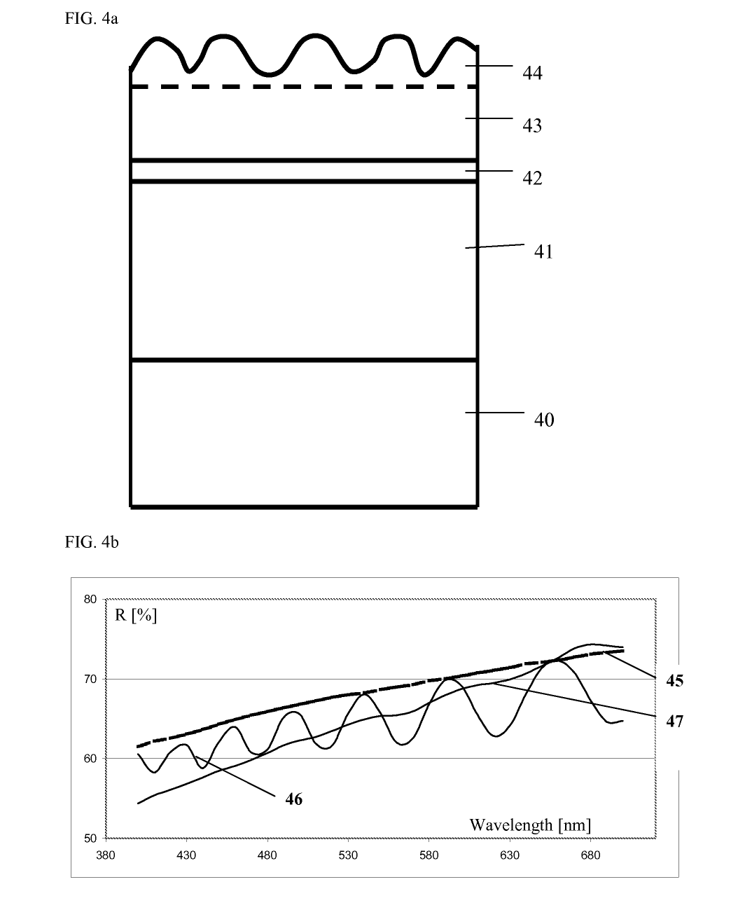

In another preferred embodiment depicted in FIG. 4a, the substrate 40 consists out of a flat or curved plastic material like PC-ABS. Firstly a 10 . . . 15 μm thick base coat 41 is applied by painting. In a second step a metal layer consisting of aluminium, indium, chromium, silicon, iron, nickel, tin or alloys of these materials 42 with a thickness of 5 to 100 nm is applied in a vacuum process. Third, a thick layer 2 . . . 10 μm of SiOₓ 43 is applied by while removing the patterning device. Forth an about 1 . . . 2 μm thick SiOₓ 44 layer is applied with the patterning device. The patterning device consists out of a 0.2 mm thick metal foil with a regular pattern of holes with a diameter of 0.15 mm, spaced about 0.3 mm.

FIG. 4b depicts the optical reflection pattern of a thin Indium film on a PC-ABS substrate 45, with hard protective layer but without the patterned layer 46 and with hard protective layer and with the patterned layer 47 described in step 4. The suppression of the interference effect and its associated fringes is apparent.

### Embodiment 3

In another preferred embodiment, the substrate consists out of a flat or curved transparent plastic material. Firstly a 10 . . . 15 μm thick base coat is applied by painting. In a second step a metal layer with a thickness of 10 to 100 nm is applied in a vacuum process. Third, a thick layer 2 . . . 10 μm of SiOₓ is applied by while removing the patterning device. Forth an about 1 . . . 2 μm thick SiOₓ layer is applied with the patterning device. The patterning device consists out of a 0.2 mm thick metal foil with a regular pattern of holes with a diameter of 0.15 mm, spaced about 0.3 mm. Fifth an additional SiOₓ layer is applied with a different patterning device. The patterning device consists out of a 0.2 mm thick textile mesh with a regular pattern of holes with a wire diameter of 0.065 mm and a mesh opening of 140 μm. Sixth, the surface is treated with a commercially available product to form a thin (less than 10 nm) water repellent layer.

As a result of the combined effect of the water repellent coating and the surface patterning, the surface turns itself super hydrophobic and a contact angle with water of superior 150° is achieved.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope. Having fully described several embodiments of the present invention, many other equivalent or alternative methods of depositing the protective PECVD layer according to the present invention will be apparent to those skilled in the art. These alternatives and equivalents are intended to be included within the scope of the present invention.

1. A chemical vapor coating formed on a substrate in an essentially vacuum pressure chamber, the coating comprising a patterned coating, preferably a substantially wave-like coating.

2. The coating of claim 1, wherein the thickness of the coating is between 20-5 000 nm.

3. The coating of claim 1, wherein a structure provided with numerous perforations has been placed substantially above the substrate.

4. The coating of claim 3, wherein said structure is a perforated plate.

5. The coating of claim 3, wherein said structure is a mesh-like structure.

6. The coating of claim 3, wherein said structure is a slot-like structure.

7. The coating of claim 1, wherein a cathode has been placed substantially below the substrate, the cathode has an insulating structure, said insulating structure contains a set of electro-conductive ridges displaced by a distance from each other, and the ridges have a connection to the cathode.

8. The coating of any of the claim 1, wherein the coating is a SiOₓ based coating.

9. The coating of claim 1, wherein the coating is a TiOₓ based coating.

10. The coating of claim 1, wherein the coating is formed by numerous layers whose diameter is in between 1-100 μm, heights in between 0.01-0.5 μm and the distance between said heights in between 10-500 μm.

11. The coating of claim 1, wherein the substrate is a substrate of transparent plastic material.

12. The coating of claim 1, wherein the substrate is a substrate of metal.

13. The coating of claim 1, wherein the substrate is a substrate of opaque plastic material.

14. The coating of claim 1, wherein said coating is a superhydrophobic coating, in which the water contact angle is higher than 100 degrees.

15. The coating of claim 1, wherein a first layer with a preferable thickness of 2-10 μm has been first formed on the substrate without the structure that gives a patterned shape, and that a second layer with a preferable thickness of 1-2 μm has been formed on top of the first layer with the aid of the structure that gives a patterned shape.

16. The coating of claim 11, wherein a hard protective layer has been formed on a substrate of transparent plastic material without the structure that gives a patterned shape, and that a second layer having a patterned shape has been formed on top of the hard protective layer with the aid of the structure that gives a patterned shape.

17. The coating of claim 11, wherein a first layer with a preferable thickness of 10-15 μm has been formed on a substrate of transparent plastic material, and that a second layer with a preferable thickness of 10-100 nm has been formed on top of the first layer, and that a third layer with a preferable thickness of 2-10 μm has been formed on top of the second layer without the structure that gives a patterned shape, and that a fourth layer with a preferable thickness of 1-2 μm has been formed on top of the third layer with the aid of the structure that gives a patterned shape.

18. A method for depositing a patterned coating, comprising:
depositing a patterned coating directly onto a curved or planar substrate through a patterning device by plasma enhanced chemical vapor deposition.

19. The method of claim 18, wherein the patterning device comprises perforations to obtain a patterned coating comprising a plurality of protrusions.

20. The method of claim 19, wherein the diameter of the protrusions is between 1 to 100 μm, the height of the protrusions between 0.01 to 0.5 μm and the spacing between the protrusions 10 to 500 μm.

21. A method of forming a chemical vapor coating formed on a substrate, the method comprising, conducting a gas mixture to a substrate in a substantially vacuum pressure chamber, and providing the substrate with a structure having numerous perforations, whereby a patterned coating is formed on the surface of the substrate, preferably a substantially wave-like coating, with the aid of said structure having numerous perforations.

22. The method of claim 21, wherein said patterned coating is formed with the aid of plasma enhanced chemical vapor deposition in a substantially vacuum pressure chamber.

23. The method of claim 22, wherein plasma is produced by RF or microwave technique said substrate being located in the same chamber in which plasma is produced and removed.

24. The method of claim 22, wherein the substrate located in the substantially vacuum pressure chamber is connected to an RF power supply.

25. A product comprising a substrate and a chemical vapor coating formed on the substrate in an essentially vacuum pressure chamber, wherein the coating is a patterned coating, preferably a substantially wave-like coating.
